(19) United States
(12) Patent Application Publication
(10) Pub. No.: US 2013/0032508 A1
(43) Pub. Date: Feb. 7, 2013

(54) TRAY FOR SEMICONDUCTOR INTEGRATED CIRCUITS

(71) Applicant: Seiji Azuma, Tokyo (JP)

(72) Inventor: Seiji Azuma, Tokyo (JP)

(73) Assignee: SHINON CORPORATION, Tokyo (JP)

(21) Appl. No.: 13/642,268

(22) PCT Filed: Jun. 21, 2010
(86) PCT No.: PCT/JP2010/004108

§ 371 Date: Oct. 19, 2012

(30) Foreign Application Priority Data
May 6, 2010 (JP) 2010-106539

(51) Int. Cl. H01L 21/673

(52) U.S. Cl. 206/710

(57) ABSTRACT

The present invention is directed to a tray for semiconductor integrated circuits that enables a BGA semiconductor integrated circuit to be repositioned appropriately in a pocket even if a corner part thereof may fall in a corner part of the recess on the inner bottom surface of a packing pocket. Tapered inner side walls 9 are tilted downward to the inner bottom surface at an angle within the range suggested in FIG. 10 and the ends of adjacent tapered inner side walls 9 are connected by a curving line in the recess 5 provided in a packing pocket 2 of the tray 1 for semiconductor integrated circuits.

### BACKGROUND OF THE INVENTION

1. Field of the Invention

The present invention relates to a tray for packaging semiconductor integrated circuits such as ICs, and more specifically, a tray suitable for packaging BGA (Ball Grid Array) semiconductor integrated circuits having multiple terminals on the bottom surface thereof.

2. Description of Related Art

Conventionally, BGA semiconductor integrated circuits are packaged in a tray that is configured as disclosed in Japanese Patent Application Publication No. 11-145315 (Pages 1 to 7, FIGS. 1 to 7) for storage and carriage, for example.

As illustrated in FIG. 11, this tray is adapted to package individual semiconductor integrated circuits in multiple rectangular pockets 14 defined by vertical and horizontal partition frames 12, 13 disposed on the upper surface of the tray 11.

in addition, as illustrated in FIG. 12, on the inner bottom surface of a pocket 14, lies a recess 15 having a flat surface shape which is slightly smaller than and approximately analogous to the bottom surface of a semiconductor integrated circuit and having a longer depth than a height of terminals arranged on the bottom surface of a semiconductor integrated circuit.

Accordingly, as illustrated in FIG. 13, a semiconductor integrated circuit is to be packed into the upper side of a pocket 14 with the terminals 17 on the bottom surface thereof being accommodated in the recess 15 of a pocket 14 and circumference of the bottom surface of the semiconductor integrated circuit 16 being supported on a step 18 provided between the recess 15 and the partition frames 12, 13.

However, given that a semiconductor integrated circuit is subjected to rotational displacement or the like in the horizontal direction (relative to upper and lower surfaces thereof) while the semiconductor integrated circuit is being packed in a pocket into the upper side of the pocket of the tray through an automated machine, a corner 16a of the semiconductor integrated circuit 16 may fall in a corner part of the recess 15 of the pocket 14 as illustrated in FIG. 14, and the tray 11 may sometimes be stored without repositioning such semiconductor integrated circuit 16 in the pocket 14.

This may cause the semiconductor integrated circuit to break when the trays are piled, otherwise this is likely to cause implementation failures during implementation process through an automated machine.

### SUMMERY OF THE INVENTION

The present invention is directed to provide a tray for semiconductor integrated circuits that enables a corner part of a semiconductor integrated circuit to eject from a corner part of a recess on the inner bottom surface of a packing pocket even if the corner part thereof is about to fall in a corner part of the recess on the inner bottom surface of the packing pocket, and, even in the case where the semiconductor integrated circuit is placed with a corner part thereof fallen in a corner part of the recess on the inner bottom surface of a packing pocket, enables the corner part of the semiconductor integrated circuit to eject from the corner part of the recess on the inner bottom surface of the packing pocket by vibration of the tray while being carried, and the semiconductor integrated circuit to be repositioned appropriately in the pocket.

To solve the above-described problems, a packaging tray for semiconductor integrated circuits according to one aspect of the present invention comprising on at least the upper surface thereof multiple rectangular packing pockets for semiconductor integrated circuits defined by vertical and horizontal partition frames, each pocket including, on the inner bottom surface thereof, a recess having a flat surface shape which is slightly smaller than and approximately analogous to the bottom surface of a semiconductor integrated circuit and having a longer depth than a height of terminals on the bottom surface of a semiconductor integrated circuit and including, between the recess and the base portions of the partition frames, a supporting step for supporting circumference of the bottom surface of a semiconductor integrated circuit, wherein inner side walls of the recess are tapered downward to the inner bottom surface with the ends of adjacent inner side walls being connected by a curving line.

The taper angle of each inner side wall of a recess tilted downward to the inner bottom surface must be designed within a range from 20 degrees to an angle that prevents the inner side walls from contacting the terminals on the bottom surface of a semiconductor integrated circuit while the semiconductor integrated circuit is being packed in a pocket.

With respect to the tray for semiconductor integrated circuits according to the present invention, the inner side walls of the recess on the inner bottom surface of a pocket of the tray are tapered downward to the inner bottom surface with the ends of adjacent inner side was in the recess being connected by a curving line. Accordingly, in the case where a corner part of a semiconductor integrated circuit is about to fall in a corner part in the recess on the inner bottom surface of a pocket, the corner part of the semiconductor integrated circuit is tangentially contacting a curving corner surface of the inner side walls of the recess. At the same time, the side portions that extend from the corner part of the semiconductor integrated circuit are not contacting with the inner side walls of the recess on the inner bottom surface of the pocket. his contacting state is so to say “a tangent state” with low friction resistance. For example, given that a corner part of a relatively large semiconductor integrated circuit having a dimension of 0.59×0.59 in. (15×15 mm) or larger is about to fall in a corner part in a recess, the corner part of the semiconductor integrated circuit tangentially contacting a curving corner surface of the tapered inner side walls is to slide up the tapered slope of the corner surface and is to eject from the recess by vibration while the semiconductor integrated circuit is being packed and by its own weight with the terminals arranged on the bottom surface of the semiconductor integrated circuit being accommodated in the recess on the inner bottom surface of the pocket. Further, circumference of the bottom surface of the semiconductor integrated circuit is to be placed on a step between the recess and the partition frames around the pocket, so as to enable the semiconductor integrated circuit to be repositioned appropriately in the pocket.

Whereas, given that a corner part of a relatively small semiconductor integrated circuit having a dimension of 0.39×0.39 in. (10×10 mm) or smaller is about to fall in a corner part in the recess on the inner bottom surface of a pocket, the corner part is unlikely to slide up the tapered slope of the corner surface in the recess and eject from the recess because the semiconductor integrated circuit is too light to slide up even though the corner part of the semiconductor integrated circuit is tangentially contacting the curving corner surface of the tapered inner side walls tilted downward to the inner bottom surface as described above. However, by vibration while the tray is being carried from this packaging process, during which the semiconductor integrated circuits are packaged in the tray, to the next process, the corner part of the semiconductor integrated circuit tangentially contacting the corner surface is to slide up the tapered slope of the corner surface and is to eject from the recess with the terminals arranged on the bottom surface of the semiconductor integrated circuit being accommodated in the recess on the inner bottom surface of the pocket, and circumference of the bottom surface of the semiconductor integrated circuit is to be placed on a step between the recess and the partition frames around the pocket, so that the semiconductor integrated circuit can be repositioned appropriately in the pocket.

Accordingly, it is possible to reduce breakage of the semiconductor integrated circuit when the trays are piled and implementation failures during implementation process through an automated machine.

### BRIEF DESCRIPTION OF THE DRAWINGS

FIG. 1 is a plan view illustrating an example of a tray for semiconductor integrated circuits according to the present invention.

FIG. 2 is an enlarged plan view of a pocket in the tray for semiconductor integrated circuits in FIG. 1.

FIG. 3 is an enlarged cross-sectional view taken along the line A-A shown in FIG. 2.

FIG. 4 illustrates the cross-sectional pocket in the normal packing state of a semiconductor integrated circuit packed in a pocket.

FIG. 5 illustrates a pocket in the normal packing state of a semiconductor integrated circuit packed in a pocket.

FIG. 6 illustrates a pocket in the abnormal packing state of a semiconductor integrated circuit packed in a pocket.

FIG. 7 illustrates the part of the pocket cross-sectioned along the line B-B, circled with E on the line B-B in FIG. 6.

FIG. 8 is a cross-sectional view illustrating a contacting state between the semiconductor integrated circuit and a tapered curving surface at the part circled with E on the line C-C in FIG. 6.

FIG. 9 illustrates the part of the pocket cross-sectioned along the line D-D, circled with E on the line D-D in FIG. 6.

FIG. 10 is results of comparison tests of repositioning performance of trays for semiconductor integrated circuits.

FIG. 11 is a plan view illustrating an example of a conventional tray for semiconductor integrated circuits.

FIG. 12 is an enlarged cross-sectional view, taken along the line B-B in FIG. 10, of a pocket of the tray for semiconductor integrated circuits in FIG. 10.

FIG. 13 illustrates a cross-sectional view of a semiconductor integrated circuit packed in a pocket in the normal packing state.

FIG. 14 illustrates a cross-sectional view of a semiconductor integrated circuit packed in a pocket in the abnormal packing state.

### DETAILED DESCRIPTION OF THE INVENTION

Hereinafter, embodiments of a tray for semiconductor integrated circuits according to the present invention will be described in detail based on examples illustrated in the attached drawings.

The tray for semiconductor integrated circuits according to the present invention is used for packaging BGA (Ball Grid Array) semiconductor integrated circuits and thereafter a plurality of trays maybe piled. The upper surface of the tray functions as a packaging container for packaging semiconductor integrated circuits whereas the lower surface thereof functions as a lid of the packaging container.

As illustrated in FIG. 1, the upper surface of a tray 1 is provided with multiple pockets 2 for packaging semiconductor integrated circuits, and the pockets 2 are defined by partition frames 3, 4 with each frame being wider toward the bottom and rising upward so that a semiconductor integrated circuit can fit in the pocket.

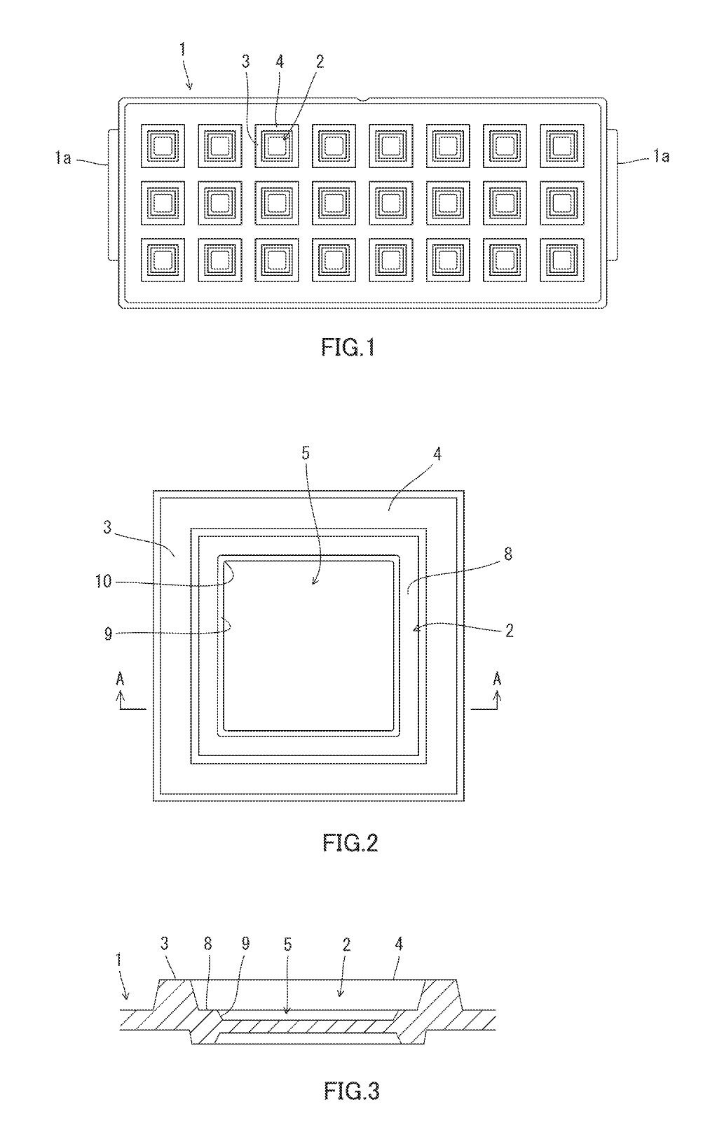

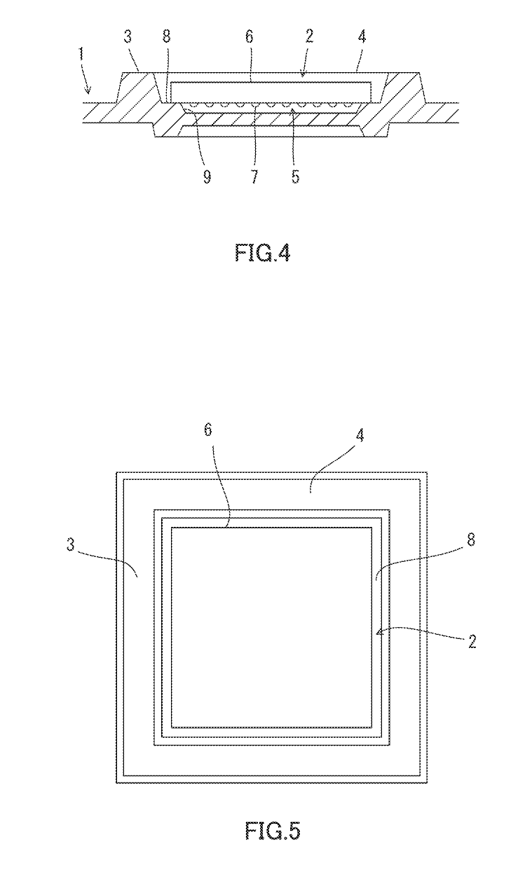

In addition, as illustrated in FIGS. 2 and 3, a pocket 2 has a recess 5 on the inner bottom surface thereof, and the recess 5 has a flat surface shape which is slightly smaller than and approximately analogous to the bottom surface of a semiconductor integrated circuit 6 to be packed (refer to FIG. 4) and has a longer depth than a height of the terminals 7 (refer to FIG. 4) on the bottom surface of a semiconductor integrated circuit 6 (refer to FIG. 4).

Further, a step 8 for supporting circumference of the bottom surface of a semiconductor integrated circuit 6 (refer to FIG. 4) is provided between the recess 5 in a pocket 2 and the base portions of the partition frames 3, 4.

As illustrated in Figs . 2 and 3, the inner side walls of the recess 5 in a pocket 2 are formed as tapered inner side walls 9 tilted downward to the inner bottom surface with the ends of adjacent tapered inner side walls 9 being connected by a curving line to form a tapered curving surface 10.

Hereinafter, effects of the aforementioned tray 1 for semiconductor integrated circuits according to the present invention will be described.

Normally, a packing state of a semiconductor integrated circuit 6 being packed appropriately in the pocket 2 of the tray 1 for semiconductor integrated circuits is the normal packing state in which the terminals 7 on the bottom surface of a semiconductor integrated circuit 6 are accommodated in the recess 5 of the pocket 2 with circumference of the bottom surface being supported on a step 8 between the recess 5 and the partition frames 3, 4, as illustrated in FIGS. 4 and 5.

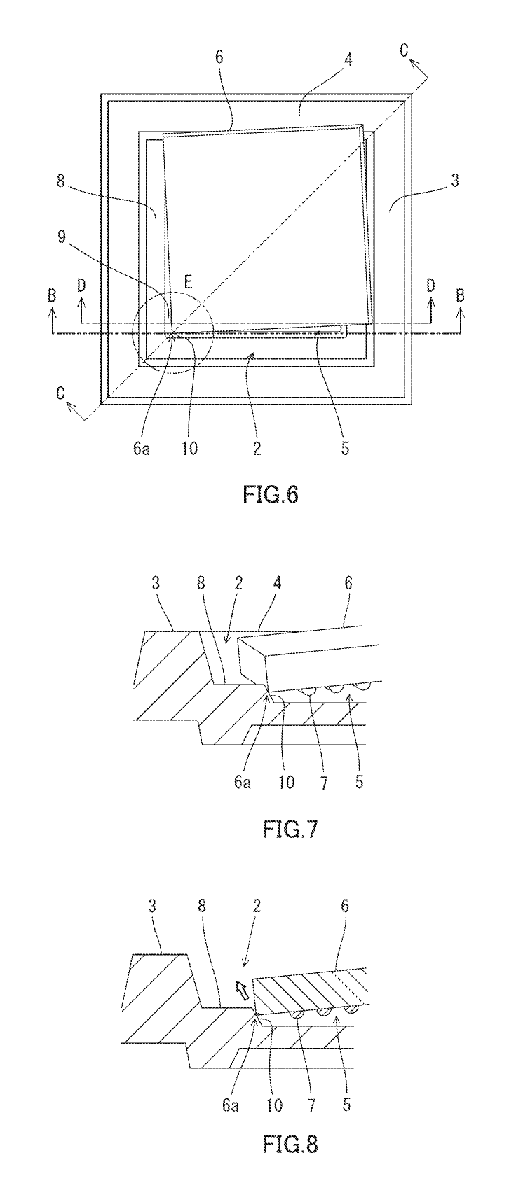

Contrary to the aforementioned normal packing state, the state in which a semiconductor integrated circuit 6 is placed in a pocket 2 of the tray 1 for semiconductor integrated circuits while being rotated horizontally is the abnormal packing state in which one corner 6a out of four corners of the semiconductor integrated circuit 6 may fall in a tapered curving surface 10 as a corner part in the recess 5 in the pocket 2, as illustrated in FIG. 6.

in addition, a corner 6a of the semiconductor integrated circuit 6 in the abnormal state may tangentially contact a tapered curving surface 10 in the recess 5 in the pocket 2 as illustrated in FIGS. 7 and 8.

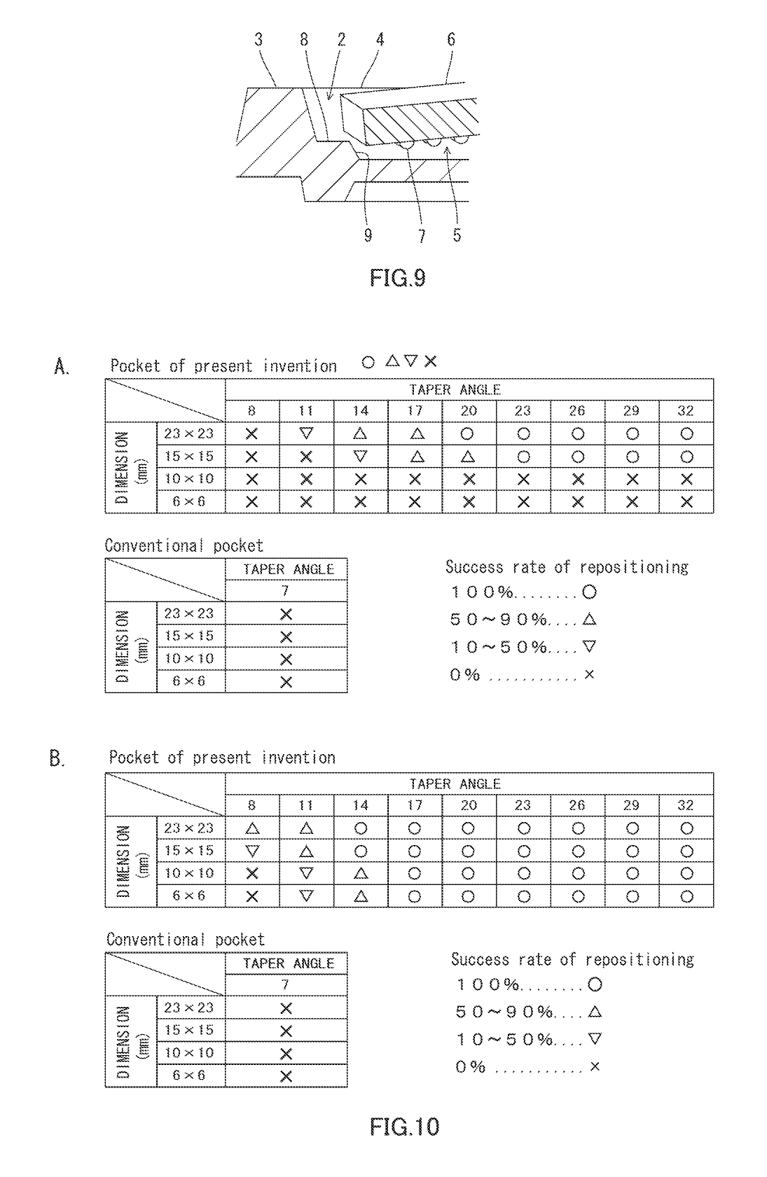

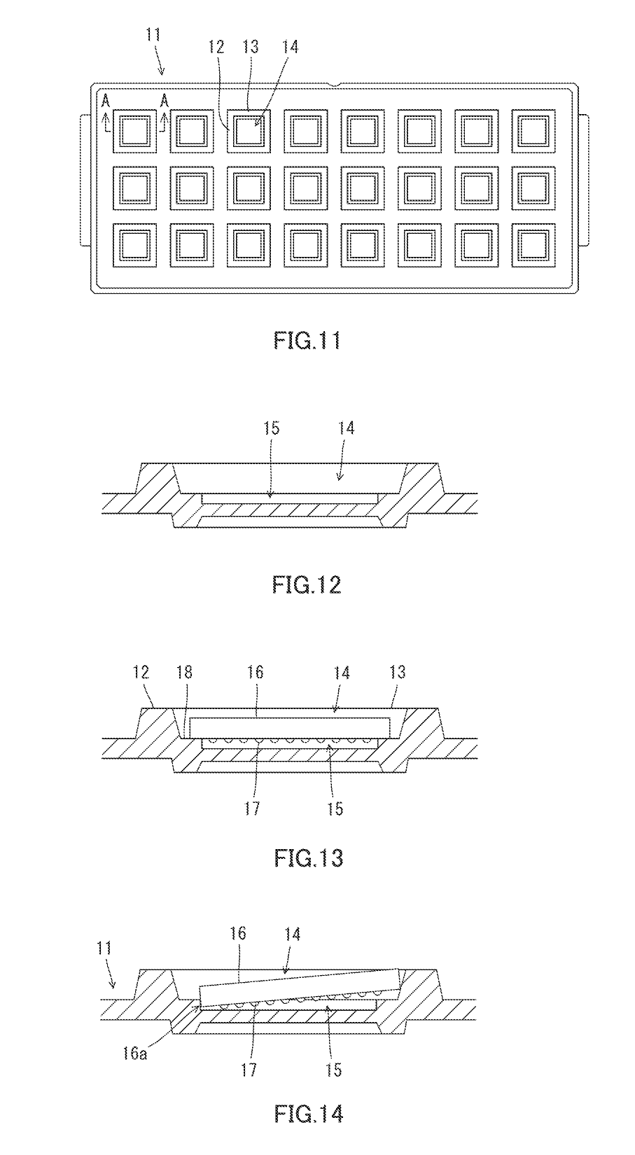

Further, in the state shown in FIGS. 7, 8, two side portions (only one side portion is shown in the present embodiment) that extend from the corner 6a never contact the tapered inner side walls 9 in the recess 5 in the pocket 2 as illustrated in FIG. 9.

On one hand, given that a relatively large semiconductor integrated circuit having a dimension of 0.59×0.59 in. (15×15 mm) or larger is placed in the abnormal state, the corner 6a of the semiconductor integrated circuit 6 tangentially contacting a tapered curving surface 10 in the recess 5 in a pocket 2 is to slide up the tapered slope of the curving surface 10 and is to eject from the recess 5 by vibration while the semiconductor integrated circuit is being packed and its own weight.

On the other, given that a relatively small semiconductor integrated circuit having a dimension of 0.39×0.39 in. (10×10 mm) or smaller is placed in the abnormal state, the corner 6a of a semiconductor integrated circuit 6 tangentially contacting a tapered curving surface 10 in the recess 5 in a pocket 2 is to slide up the tapered slope of the curving surface 10 and is to eject from the recess 5 by vibration while the tray is being carried from this packaging process, during which semiconductor integrated circuits are packaged in the tray, to the next process.

Since the adjacent two side portions that extend from a corner 6a of the semiconductor integrated circuit 6 never contact tapered inner side walls 9 in the recess 5 in a pocket 2 when the corner 6a of the semiconductor integrated circuit 6 ejects as described above, friction resistance at the time of ejection generates only at the corner 6a in “a tangent state” with low friction resistance. Thus, comparison tests of repositioning performance of trays for semiconductor integrated circuits in FIG. 10 have resulted in that a relatively large semiconductor integrated circuit having a dimension of 0.59×0.59 in. (15×15 mm) or larger can eject easily by vibration while the semiconductor integrated circuit is being packed and by its own weight whereas a relatively small semiconductor integrated circuit having a dimension of 0.39×0.39 in. (10×10 mm) or smaller ejects easily by vibration while the tray is being carried from this packaging process, during which semiconductor integrated circuits are packaged in the tray, to the next process.

Test conditions for the comparison tests of repositioning performance of trays for semiconductor integrated circuits in FIG. 10 will be described below.

In FIG. 10A, semiconductor integrated circuits under the condition of being rotated horizontally are placed (which are about to fall) in a pocket according to the present invention and a conventional reference pocket.

In FIG. 10B, a pocket according to the present invention and a conventional reference pocket are subjected to vibration equal to vibration while being carried, under the condition that one corner part of a semiconductor integrated circuit has fallen in a corner part in the recess on the inner bottom surface of a pocket.

Under these conditions, semiconductor integrated circuits having different dimension have been tested 10 times respectively, and a circle “ο” indicates the result of 100% success rate of repositioning, a triangle “Δ” is for 50 to 90%, an inverted triangle “∇” is for 10 to 50%, and a cross “x” is for 0%.

While the lower limit of the taper angle of each inner side wall in the recess 5 in the aforementioned pockets 2 is preferably 20 degrees, the upper limit of the taper angle depends on the design, however, the taper angle must be designed within the predetermined range of angles that prevents the inner side walls from contacting the terminals 7 arranged on the bottom surface of a semiconductor integrated circuit 6 to be packed.

in addition, the range and the curvature of a curving portion in each tapered curving surface 10 in the recess 5 in a pocket 2 must be designed so that the two side portions that extend from a corner 6a of a semiconductor integrated circuit 6 (which is about to fall in the recess 5) never contact tapered inner side walls 9 in the recess 5 in a pocket 2.

The form of the partition frames 3, 4 shown in the present embodiment is illustrative only and may be modified in any form, such as discontinuous enclosure of the four corners or enclosure of the sides only, instead of continuous enclosure of the whole circumference of a pocket 2 as illustrated in the present embodiment, unless the semiconductor integrated circuit 6 is enclosed in an unstable manner.

Reference numeral 1a in FIG. 1 of the embodiment refers to a handle for carrying the tray 1 for semiconductor integrated circuits.

What is claimed is:

1. A packaging tray for semiconductor integrated circuits comprising on at least the upper surface thereof:
multiple rectangular packing pockets for semiconductor integrated circuits defined by vertical and horizontal partition frames, each pocket including, on the inner bottom surface thereof, a recess having a flat surface shape which is slightly smaller than and approximately analogous to the bottom surface of a semiconductor integrated circuit and having a longer depth than a height of terminals on the bottom surface of a semiconductor integrated circuit and including, between the recess and the base portions of the partition frames, a supporting step for supporting circumference of the bottom surface of a semiconductor integrated circuit,
wherein inner side walls of the recess are tapered downward to the inner bottom surface, the ends of adjacent inner side walls being connected by a curving line.

2. The housing tray for semiconductor integrated circuits according to claim 1,
Wherein the taper angle of each inner side walls of the recess tilted downward to the inner bottom surface is designed within a range from 20 degrees to an angle that prevents the inner side walls from contacting the terminals on the bottom surface of a semiconductor integrated circuit while the semiconductor integrated circuit is being packed in a pocket.
